(19) United States
(12) Patent Application Publication
(10) Pub. No.: US 2025/0016938 A1
(43) Pub. Date: Jan. 9, 2025

(54) DISPLAY DEVICE

(71) Applicant: LG ELECTRONICS INC., Seoul (KR)

(72) Inventor: Seunggyu KANG, Seoul (KR)

(73) Assignee: LG ELECTRONICS INC., Seoul (KR)

(21) Appl. No.: 18/659,929

(22) Filed: May 9, 2024

(30) Foreign Application Priority Data
Jul. 3, 2023 (KR) 10-2023-0085710

(51) Int. Cl. H05K 5/02

(52) U.S. Cl. CPC H05K 5/02

(57) ABSTRACT

Disclosed is a display device. The display device includes: a display panel; a material complexed plate located in a rear of the display panel; and a side frame which is located between the display panel and the material complexed plate, is fixed to the material complexed plate, and to which the display panel is coupled, wherein the material complexed plate includes: a front skin which forms a front surface; a rear skin which forms a rear surface and faces the front skin; and a core which is located between the front skin and the rear skin, and contains fibers.

### CROSS-REFERENCE TO RELATED APPLICATION(S)

Pursuant to 35 U.S.C. § 119, this application claims the benefit of earlier filing date and right of priority to Korean Application No(s). 10-2023-0085710, filed on Jul. 3, 2023, the contents of which are all incorporated by reference herein in its entirety.

### TECHNICAL FIELD

This disclosure relates to a display device.

### BACKGROUND

As the information society develops, the demand for display devices is also increasing in various forms. In response to this, in recent years, various display devices such as Liquid Crystal Display Device (LCD), Plasma Display Panel (PDP), Electroluminescent Display (ELD), Vacuum Fluorescent Display (VFD), and Organic Light Emitting Diode (OLED) have been researched and used.

Among these, a display device using organic light emitting diode (OLED) has the advantage of being implemented in an ultra-thin form because it has superior brightness and viewing angle compared to liquid crystal display device and does not require a backlight unit.

Recently, much research has been conducted to ensure the rigidity and structural stability of a large-screen ultra-thin display device.

### SUMMARY

The disclosure has been made in view of the above problems, and may intend to ensure the structural rigidity of a large-screen ultra-thin display device.

The disclosure may further intend to ensure the structural stability of a display device.

The disclosure may further intend to improve the flatness of the frame of a display device.

In accordance with an aspect of the present disclosure, a display device includes: a display panel; a material complexed plate located in a rear of the display panel; and a side frame which is located between the display panel and the material complexed plate, is fixed to the material complexed plate, and to which the display panel is coupled, wherein the material complexed plate includes: a front skin which forms a front surface; a rear skin which forms a rear surface and faces the front skin; and a core which is located between the front skin and the rear skin, and contains fibers.

### BRIEF DESCRIPTION OF THE DRAWINGS

The above and other objects, features and advantages of the present disclosure will be more apparent from the following detailed description in conjunction with the accompanying drawings, in which:

FIGS. 1 to 34 are diagrams showing examples of a display device according to embodiments of the present disclosure.

### DETAILED DESCRIPTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

Even if an embodiment is described with reference to a specific drawing, if necessary, reference numeral not appearing in the specific drawing may be mentioned, and a reference numeral not appearing in the specific drawing may be used when the reference numeral appears in the other figures.

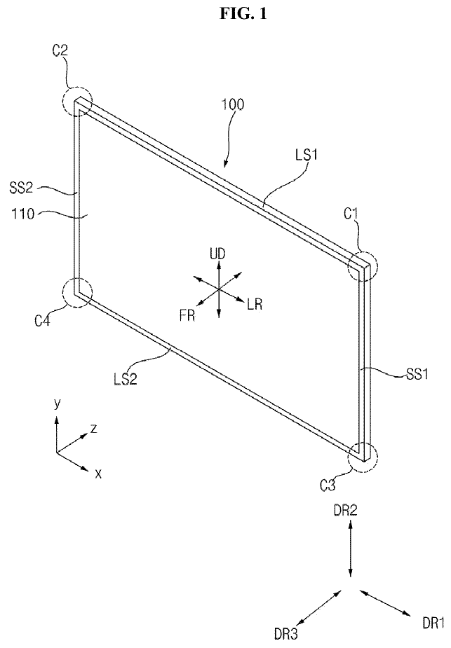

Referring to FIG. 1, a display device 100 may include a display panel 110. The display panel 110 may display an image.

The display device 100 may include a first long side LS1, a second long side LS2 opposite to the first long side LS1, a first short side SS1 adjacent to the first long side LS1 and the second long side LS2, and a second short side SS2 opposite to the first short side SS1.

For convenience of explanation, it is shown and described that the lengths of the first and second long sides LS1 and LS2 are longer than the lengths of the first and second short sides SS1 and SS2, but the lengths of the first and second long sides LS1, LS2 may be about the same as the lengths of the first and second short sides SS1 and SS2.

The direction parallel to the long side LS1, LS2 of the display device 100 may be referred to as a first direction DR1 or a left-right direction LR. The direction parallel to the short side SS1, SS2 of the display device 100 may be referred to as a second direction DR2 or an up-down direction UD.

The direction perpendicular to the long side LS1, LS2 and short side SS1, SS2 of the display device 100 may be referred to as a third direction DR3 or a forward/rearward direction FR. Here, the direction in which the display panel 110 displays an image may be referred to as a forward direction, and the opposite direction may be referred to as a rearward direction.

Hereinafter, the display panel 110 will be described by using a display panel utilizing an organic light emitting diode OLED as an example, but the display panel 110 applicable to the present disclosure is not limited thereto.

The display panel 110 forms the front surface of the display device 100, and may display an image in a forward direction. The display panel 110 may divide an image into a plurality of pixels, and output an image to be adjusted with color, brightness, and saturation for each pixel. The display panel 110 may be divided into an active area where images are displayed and a de-active area where images are not displayed. The display panel 110 may generate light corresponding to the color of red, green, or blue according to a control signal.

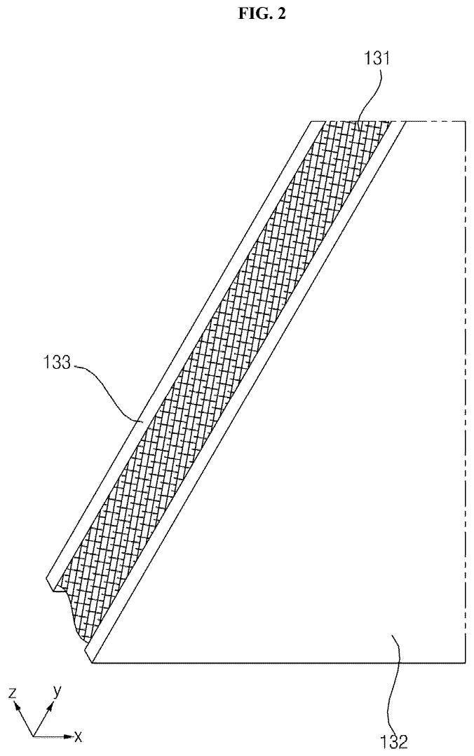

Referring to FIG. 2, a material complexed panel 130 may include a core 131, a front skin 132, and a rear skin 133. The core 131, the front skin 132, and the rear skin 133 may be coupled with each other. The material complexed panel 130 may be referred to as a fiber complexed panel 130, a fiber complexed plate 130, a material complexed plate 130, or a middle frame 130.

The front skin 132 may form the front surface of the material complexed panel 130. The rear skin 133 may form the rear surface of the material complexed panel 130. The front skin 132 and the rear skin 133 may include a metal material.

For example, the front skin 132 and the rear skin 133 may be a galvanized iron. For another example, the front skin 132 and the rear skin 133 may include aluminum A1.

For example, the thickness of the front skin 132 and the rear skin 133 may be 0.2 to 0.5 mm. As another example, the front skin 132 and rear skin 133 formed of galvanized iron may be 0.27 mm. As another example, the front skin 132 and rear skin 133 including aluminum may be 0.5 mm.

The front skin 132 and the rear skin 133 may be opposite to each other with respect to the core 131 described later. The core 131 may be located between the front skin 132 and the rear skin 133. The core 131 may include a fiber. The core 131 may be formed of a composite material. The core 131 may include a main fiber and a binder fiber. The binder fiber may be mixed between the main fibers.

The front skin 132 and/or the rear skin 133 may be coupled to the core 131 by a hot melt method. A hot melt sheet may be located between the front skin 132 and the core 131, and a hot melt sheet may be located between the rear skin 133 and the core 131. The hot melt sheet may be a film. For example, the hot melt sheet may be a film of EVA, acrylic, polyurethane, etc. with a thickness of 50 micrometers or more. The core 131 may be located between the front skin 132 and the rear skin 133 by using a hot melt sheet, and then rolled at 190 degrees Celsius for more than 1 minute.

Accordingly, the bending rigidity and/or torsional rigidity of the display device may be improved.

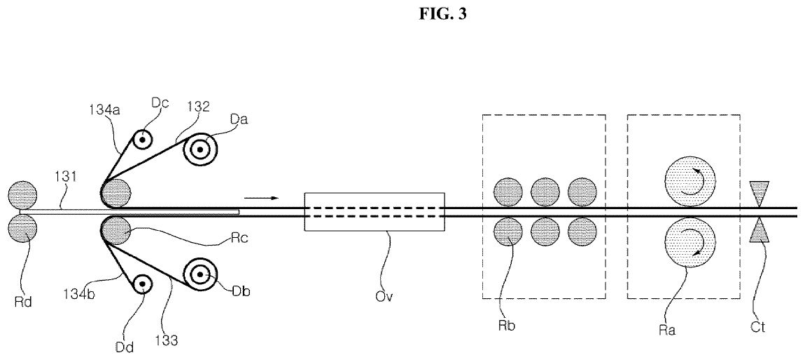

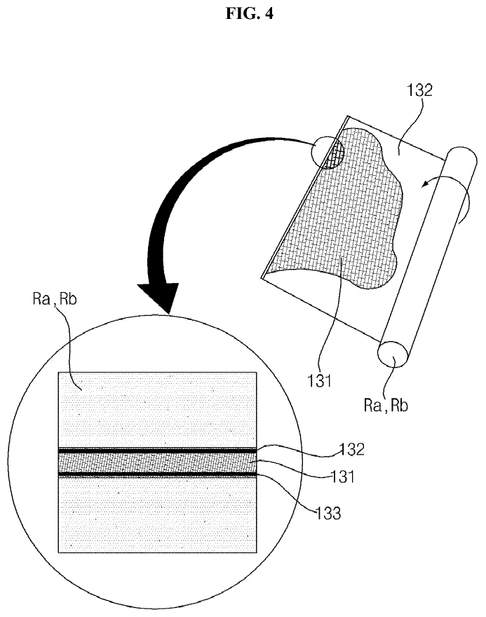

Referring to FIGS. 3 and 4, the material complexed panel 130 may be manufactured through a process of compressing the front skin 132 and the rear skin 133 to the core 131 by using a plurality of rollers. This process may be called a roll-to-roll process.

Referring to FIG. 3, as a pinch roller Ra, which functions as a drive motor, rotates, the front skin 132 is released from a front drum Da, the rear skin 133 is released from a rear drum Db, and the core 131 may be moved through a feeding roller Rd. Further, a first adhesive 134a for coupling the front skin 132 to the core 131 may be released from a first drum Dc. In addition, a second adhesive 134b for coupling the rear skin 133 to the core 131 may be released from a second drum Db. In this case, the front skin 132, the first adhesive 134a, the core 131, the second adhesive 134b, and the rear skin 133 may be stacked in the above order, and guided in the direction toward an oven Ov by a guide roller Rc. The adhesive 134a, 134b may be a hot melt sheet 134a, 134b.

The first and second adhesives 134a and 134b may be melted in the oven Ov, and each of the front skin 132 and rear skin 133 may be coupled to the core 131. For example, the melting point of the first and second adhesives 134a and 134b may be about 150° C., and the ambient temperature of the oven Ov may be about 200° C. For example, the peel-off force of the first and second adhesives 134a and 134b may be about 10 kgf or more.

The front skin 132, core 131, and rear skin 133 that have passed through the oven Ov may be guided to a pressing roller Rb according to the rotation of a pinch roller Ra, and may be compressed by the pressing roller Rb. Accordingly, the coupling force between the front skin 132, the core 131, and the rear skin 133 can be further increased. After passing the pinch roller Ra, the inter-coupled front skin 132, core 131, and rear skin 133 may be cut by a cutter Ct to manufacture a material complexed panel 130 of a certain size.

Referring to FIG. 4, the pressing roller Rb or the pinch roller Ra may contact the outer surface of each of the front skin 132 and the rear skin 133. When the pressing roller Rb or the pinch roller Ra rotates, the material complexed panel 130 may be moved in the longitudinal direction (i.e., in the left-right direction LR) of the core 131. At this time, the front skin 132 and the rear skin 133 may be sequentially coupled from one end of the core 131 to the other end in the longitudinal direction of the core 131.

In addition, the front skin 132 and rear skin 133 of the material complexed panel 130 may be formed to be flat. That is, as the rear surface of the rear skin 133, which forms the rear surface of the display device 100, is formed flat, it may be easier to perform additional work, such as painting the rear surface of the rear skin 133 or attaching a sheet for aesthetics.

Meanwhile, in addition to forming the front skin 132 and the rear skin 133 to be flat through the roll-to-roll process described above with reference to FIGS. 3 and 4, it is also possible to couple the core 131, the front skin 132, and the rear skin 133 through a process of sequentially stacking the front skin 132, the core 131, and the rear skin 133 and then coupling them.

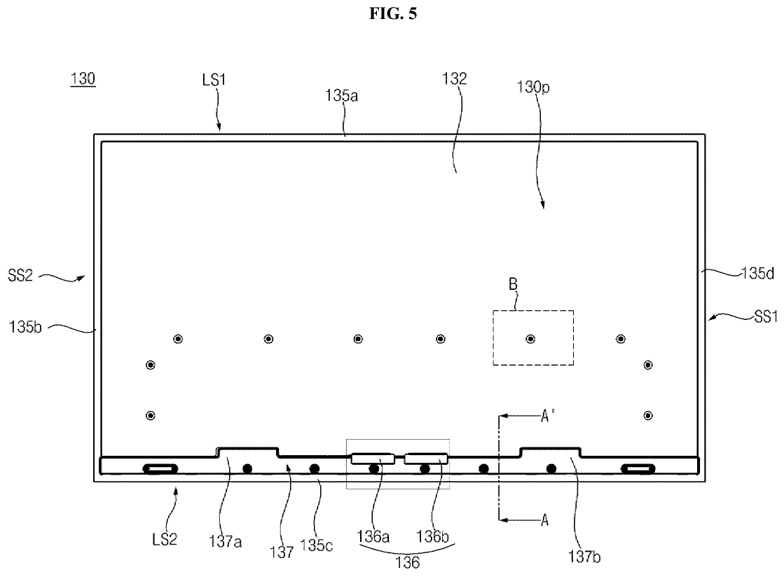

Referring to FIG. 5, the material complexed panel 130 may include a flat portion 130P, a receiving portion 137, and an outer part 135. The outer part 135 may be formed around the flat portion 130P. A first outer part 135a may be formed along the upper side of the flat portion 130P, a second outer part 135b may be formed along the left side of the flat portion 130P, a third outer part 135c may be formed along the lower side of the flat portion 130P, and a fourth outer part 135d may be formed along the right side of the flat portion 130P. The outer part 135 may be formed by pressing the flat portion 130P. The outer part 135 may form a step as it is lowered from the flat portion 130P. The thickness of the flat portion 130P may be greater than the thickness of the outer part 135.

A cable hole 136 may be formed to penetrate the front skin 132 (see FIG. 2) and the rear skin 133 (see FIG. 2) of the receiving portion 137. The cable hole 136 may be formed in the receiving portion 137 adjacent to the lower side of the flat portion 130P. There may be a plurality of cable holes 136. A first cable hole 136a may be located adjacent to a second cable hole 136b.

The receiving portion 137 may be formed between the flat portion 130P and the third outer part 135c while being adjacent to the lower side of the flat portion 130P. There may be a plurality of receiving portions 137. A first receiving portion 137a may be located between the first cable hole 136a and the second short side SS2. A second receiving portion 137b may be located between the second cable hole 136b and the first short side SS1. The receiving portion 137 may be formed by pressing the flat portion 130P. The receiving portion 137 may form a step while being lowered from the flat portion 130P and/or the outer part 135c.

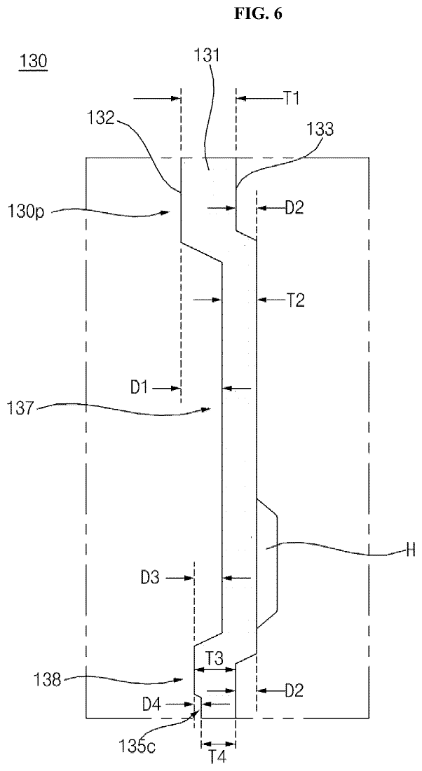

Referring to FIG. 6, the receiving portion 137 may be formed by pressing the flat portion 130P. The front skin 132 of the receiving portion 137 may form a step D1 that is lowered from the front skin 132 of the flat portion 130P. The rear skin 133 of the receiving portion 137 may form a step D2 that is raised from the rear skin 133 of the flat portion 130P. At this time, the height of the step D1 lowered from the front skin 132 of the flat portion 130P to the front skin 132 of the receiving portion 137 may be greater than the height of the step D2 that is raised from the rear skin 133 of the flat portion 130P to the rear skin 133 of the receiving portion 137. The thickness T1 of the flat portion 130P may be greater than the thickness T2 of the receiving portion 137.

The core 131 of the material complexed panel 130 may absorb external force as it is pressed in the direction from the front skin 132 of the flat portion 130P to the rear skin 133. The magnitude of the external force applied to the front skin 132 of the flat portion 130P may be greater than the magnitude of the external force applied to the rear skin 133 of the flat portion 130P. The core 131 of the material complexed panel 130 not only secures rigidity but also absorbs shock.

The thickness T4 of the third outer part 135c may be greater than the thickness T2 of the receiving portion 137. A step D2 that is raised from the rear skin 133 of the third outer part 135c to the rear skin 133 of the receiving portion 137 may be formed. The height of the step D2 between the rear skin 133 of the third outer part 135c and the rear skin 133 of the receiving portion 137 may be equal to the height of the step D2 between the rear skin 133 of the receiving portion 137 and the rear skin 133 of the flat portion 130P.

A protruding pad 138 may be formed to protrude from the front skin 132 of the third outer part 135c. The front skin 132 of the protruding pad 138 may form a step D4 that is lowered to the front skin 132 of the third outer part 135c. The height of the step D4 formed by the third outer part 135c and the protruding pad 138 may be smaller than the height of the steps D1 and D2 formed by the flat portion 130P and the receiving portion 137. A step D3 may be formed that is lowered from the front skin 132 of the protruding pad 138 to the front skin 132 of the receiving portion 137. The thickness T3 of the protruding pad 138 may be greater than the thickness T4 of the third outer part 135c, may be smaller than the thickness T1 of the flat portion 130P, and may be smaller than the thickness T2 of the receiving portion 137.

A fastening groove H may protrude from the rear skin 133 of the receiving portion 137. The fastening groove H may be recessed in the front skin 132 of the receiving portion 137 and protrude from the rear skin 133 of the receiving portion 137. The center of the fastening groove H may be penetrated.

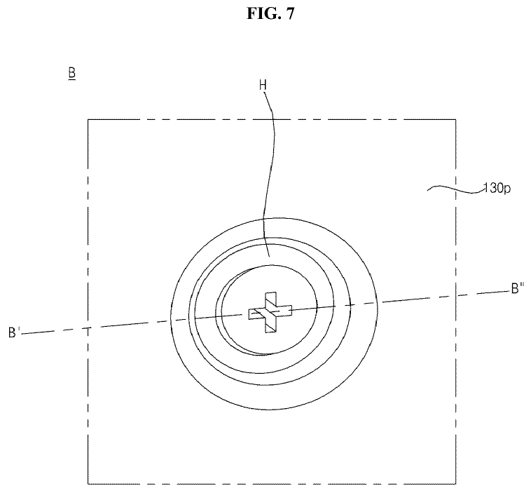

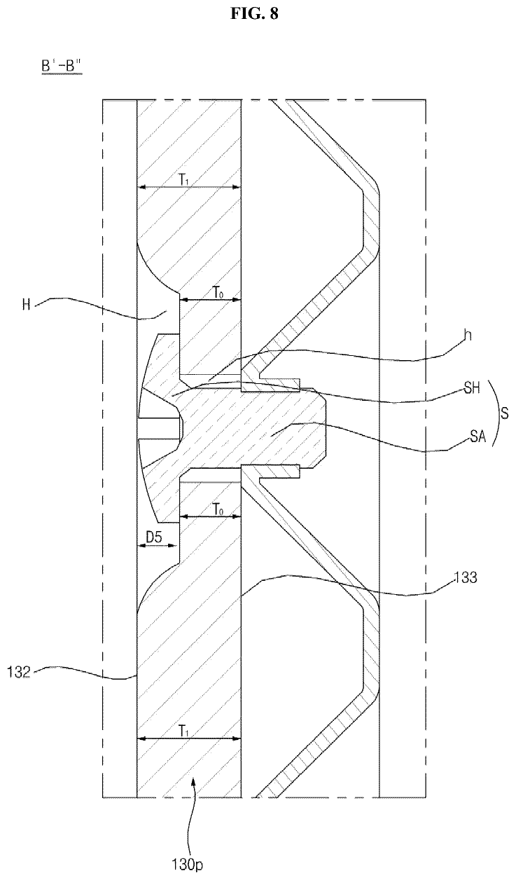

Referring to FIGS. 7 and 8, the fastening groove H may be formed in the flat portion 130P. The fastening groove H may be formed when the flat portion 130P is pressed. The front skin 132 of the fastening groove H may be formed by being recessed from the front skin 132 of the flat portion 130P. The rear skin 133 of the flat portion 130P and the rear skin 133 of the fastening groove H may form the same plane. The thickness TO of the fastening groove H may be smaller than the thickness T1 of the flat portion 130P.

A fastener h may be formed in the center of the fastening groove H. The fastener h may be formed by punching the fastening groove H. The fastener h may be formed to penetrate the front skin 132 and the rear skin 133 of the fastening groove H. The length of the shaft SA of a fastening member S may be greater than the thickness TO of the fastening groove H. The shaft SA of the fastening member S may be inserted into the fastening groove H and protrude to the outside of the rear skin 132 of the fastening groove H through the fastener h. A depth D5 of the fastening groove H may be greater than the thickness of the head SH. The head SH of the fastening member S may be hidden in the fastening groove H.

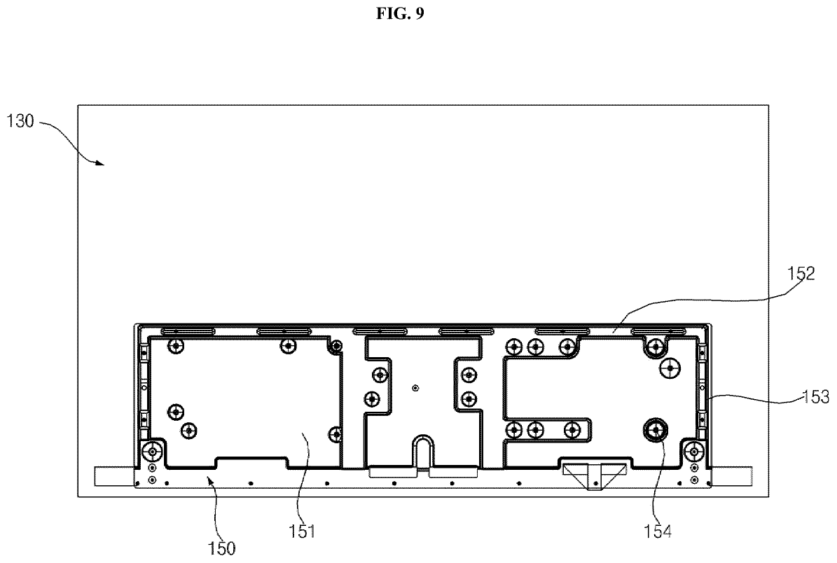

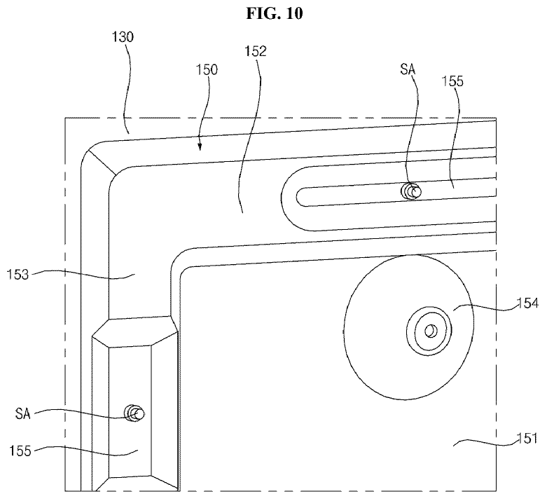

Referring to FIGS. 9 and 10 together with FIG. 8, a PCB plate 150 may be coupled to the rear of the material complexed panel 130. The PCB plate 150 may be fixed to the rear of the panel 130 of composite material by a fastening member S. The PCB plate 150 may be formed by pressing a plate 151 containing metal. The PCB plate 150 may include a horizontal portion 152, a vertical portion 153, a dome portion 154, and a recessed portion 155. The horizontal portion 152 protrudes from the front of the PCB plate 151 to the rear, and may be formed to extend long in the left-right direction of the PCB plate 151. The vertical portion 153 protrudes from the front of the PCB plate 151 to the rear, and may be formed to extend long in the vertical direction of the PCB plate 150. The dome portion 154 may protrude from the front of the PCB plate 150 to the rear. The recessed portion 155 may be recessed from the rear of the vertical portion 153 and/or the horizontal portion 152 to the front.

The shaft SA of the fastening member S may couple the material complexed panel 130 and the PCB plate 150 by penetrating the recessed portion 155 formed in the vertical portion 153 and/or the horizontal portion 152. The depth of the recessed portion 155 may be greater than the protrusion length of the shaft SA of the fastening member S that protrudes rearward by penetrating the material complexed panel 130.

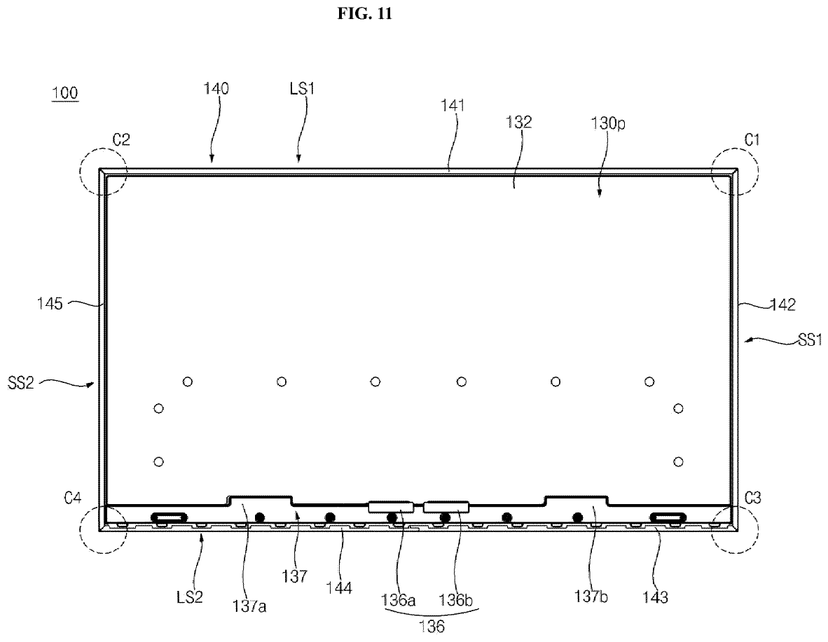

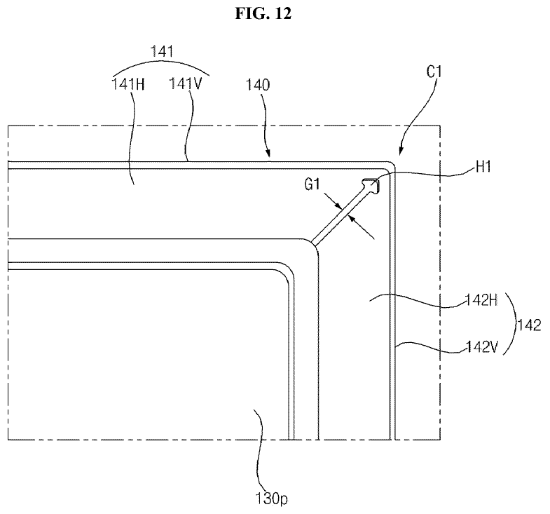

Referring to FIGS. 11 and 12, a side frame 140 may be coupled to the outer part 135 (see FIG. 5) while being adjacent to the flat portion 130P. The side frame 140 may include a first part 141, a second part 142, a third part 143, a fourth part 144, and a fifth part 145. The second part 142 may be bent at a first corner C1 from the first part 141.

The first part 141 may include a horizontal portion 141H and a vertical portion 141V. The horizontal portion 141H of the first part 141 may be fixed on the first outer part 135a (see FIG. 5). The second part 142 may include a horizontal portion 142H and a vertical portion 142V. The horizontal portion 142H of the second part 142 may be fixed on the fourth outer part 135d (see FIG. 5).

A gap G1 may be formed between the horizontal portion 141H of the first part 141 and the horizontal portion 142H of the second part 142. The vertical portion 141V of the first part 141 and the vertical portion 142V of the second part 142 may be connected while being bent. A hole H1 connected to the gap G1 may be formed between the horizontal portions 141H and 142H while being adjacent to the vertical portions 141V and 142V. The size or diameter of the hole H1 may be larger than the width of the gap G1. The description of the first corner C1 of the side frame 140 may be identically applied to a second corner C2 of the side frame 140.

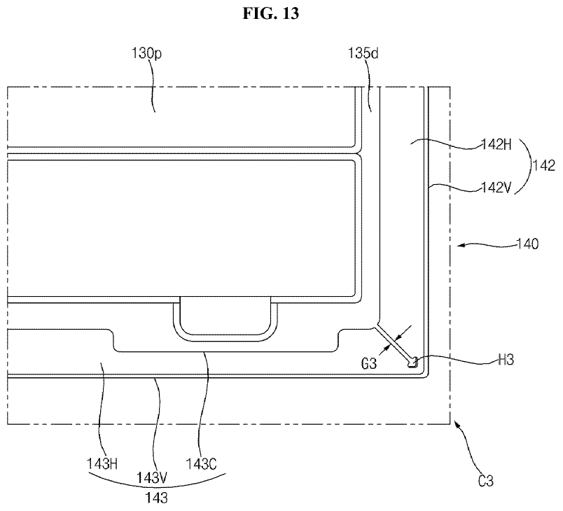

Referring to FIGS. 11 and 13, the side frame 140 may be coupled to the outer part 135 (see FIG. 5) while being adjacent to the flat portion 130P. The side frame 140 may include the first part 141, the second part 142, the third part 143, the fourth part 144, and the fifth part 145. The second part 142 may be bent at a third corner C3 from the third part 143.

The third part 143 may include a horizontal portion 143H and a vertical portion 143V. The horizontal portion 143H of the third part 143 may be fixed on the third outer part 135c (see FIG. 5). The second part 142 may include a horizontal portion 142H and a vertical portion 142V. The horizontal portion 142H of the second part 142 may be fixed on the fourth outer part 135d (see FIG. 5).

A gap G3 may be formed between the horizontal portion 143H of the third part 143 and the horizontal portion 142H of the second part 142. The vertical portion 143V of the third part 143 and the vertical portion 142V of the second part 142 may be connected while being bent. A hole H3 may be formed to be connected to the gap G3 at between the horizontal portions 143H and 142H while being adjacent to the vertical portions 143V and 142V. The size or diameter of the hole H3 may be larger than the width of the gap G3. The description of the first corner C3 of the side frame 140 may be identically applied to a fourth corner C4 of the side frame 140.

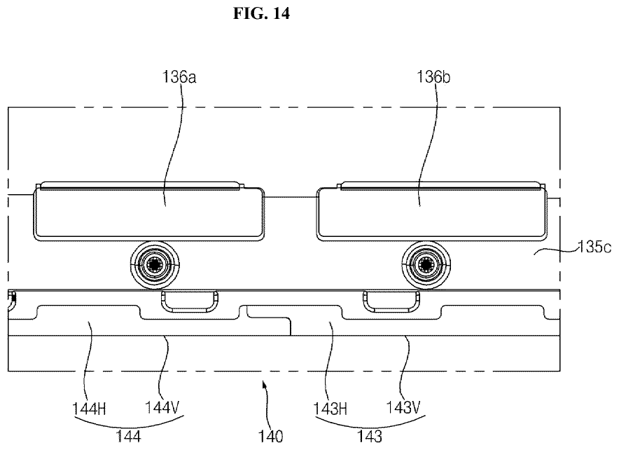

Referring to FIGS. 11 and 14, the third part 143 and the fourth part 144 of the side frame 140 may be located or fixed on the third outer part 135c. The distal end of the third part 143 of the side frame 140 may be coupled to the distal end of the fourth part 144 of the side frame 140.

The horizontal portion 144H of the fourth part 144 may contact the horizontal portion 143H and the vertical portion 143V of the third part 143. The vertical portion 144V of the fourth part 144 may contact the vertical portion 143V of the third part 143. The vertical portion 143V of the third part 143 may contact the horizontal portion 144H and the vertical portion 144V of the fourth part 144. The distal end of the third part 143 may be fixed to the distal end of the fourth part 144. For example, the distal end of the third part 143 and the distal end of the fourth part 144 may be fixed by welding.

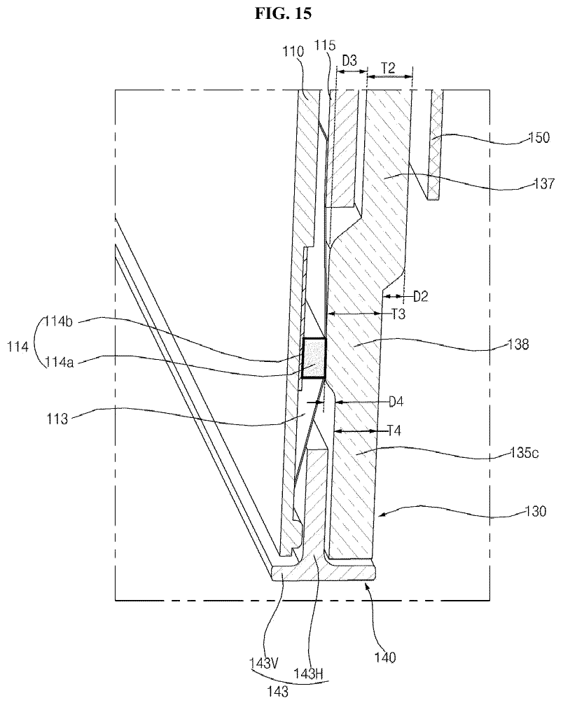

Referring to FIG. 15, the display panel 110 may be coupled or fixed to the side frame 140. The horizontal portion 143H of the side frame 140 may support the rear surface of the display panel 110, and the vertical portion 143V may cover the side surface of the display panel 110. For example, the vertical portion 143V of the third part 143 of the side frame 140 may cover the lower side of the display panel 110.

The vertical portion 143V may cover the side surface of the material complexed panel 130. For example, the vertical portion 143V of the third part 143 of the side frame 140 may cover the side surface of the third outer part 135c of the material complexed panel 130.

A flexible cable 113 may extend through between the display panel 110 and the horizontal portion 143H of the side frame 140 from the lower side of the display panel 110. The flexible cable 113 may extend through between the rear surface of the display panel 110 and the material complexed panel 130. For example, the flexible cable 113 may be a COF 113.

A source signal substrate 115 may be electrically connected to the flexible cable 113. The source signal substrate 115 may be fixed to one surface of the flexible cable 113. For example, the source signal substrate 115 may be an S-PCB 115. The source signal substrate 115 may be located in the receiving portion 137 of the material complexed panel 130.

The flexible cable 113 may be located between the display panel 110 and the protruding pad 138 of the material complexed panel 130. The flexible cable 113 may be in contact with the protruding pad 138. Heat generated from the source signal substrate 115 and/or the flexible cable 113 may be dissipated through the protruding pad 138.

A heat dissipation pad 114 may be located between the flexible cable 113 in contact with the protruding pad 138 and the rear surface of the display panel 110. The heat dissipation pad 114 may include an elastic material 114a and a conductive film 114b. The core 114a of the heat dissipation pad 114 may be formed of an elastic material, and the conductive film 114b may cover the core 114a of the heat dissipation pad 114. Accordingly, the flexible cable 113 may be maintained in contact with the protruding pad 138.

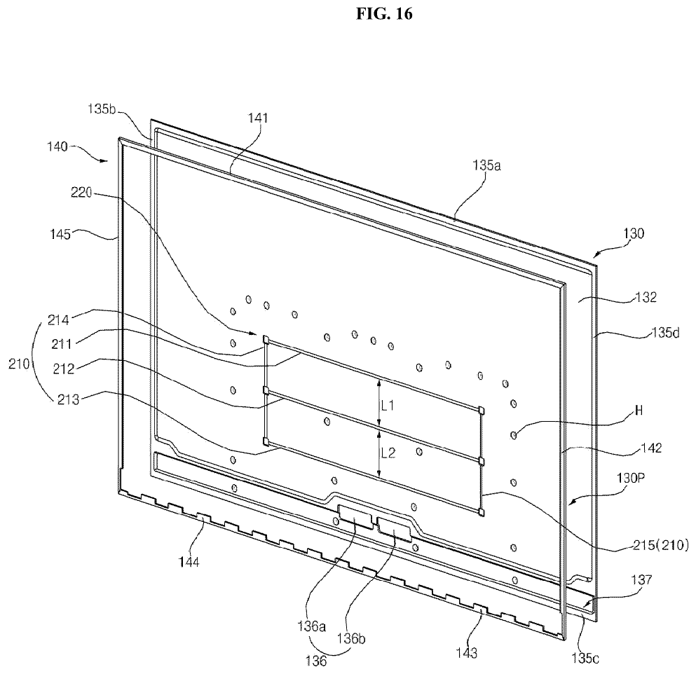

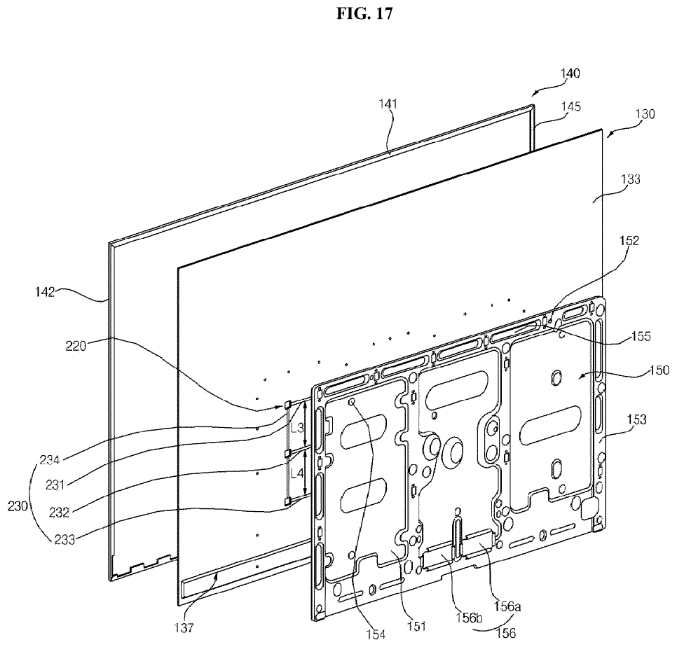

Referring to FIGS. 16 and 17, an inner frame 210, 230 may be formed on the front surface and/or rear surface of the material complexed panel 130. The inner frame 210, 230 may be referred to as a pressed frame 210, 230 or a rigid line 210, 230. The inner frame 210, 230 may be formed by sinking the front skin 132 and/or rear skin 133 of the material complexed panel 130 and compressing the core 131 (see FIG. 2).

The inner frame 210, 230 may include a front inner line 210, a rear inner line 230, and a node hole 220. The front inner line 210 may be formed by sinking the front skin 132 of the material complexed panel 130. The rear inner line 230 may be formed by sinking the rear skin 133 of the material complexed panel 130.

The front inner line 210 may include a first front horizontal line 211, a second front horizontal line 212, a third front horizontal line 213, a first front vertical line 214, and a second front vertical line 215. The first front horizontal line 214 may form the upper side of the front inner line 210. The third front horizontal line 213 may form the lower side of the front inner line 210. The second front horizontal line 212 may be located between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213. For example, a first distance L1 between the first front horizontal line 211 and the second front horizontal line 212 may be smaller than a second distance L2 between the second front horizontal line 212 and the third front horizontal line 213.

The node hole 220 may be formed at a point where the front horizontal line 211, 212, 213 and the front vertical line 214, 215 meet. The node hole 220 may be formed by penetrating the front skin 132, core 131, and rear skin 133 of the material complexed panel 130.

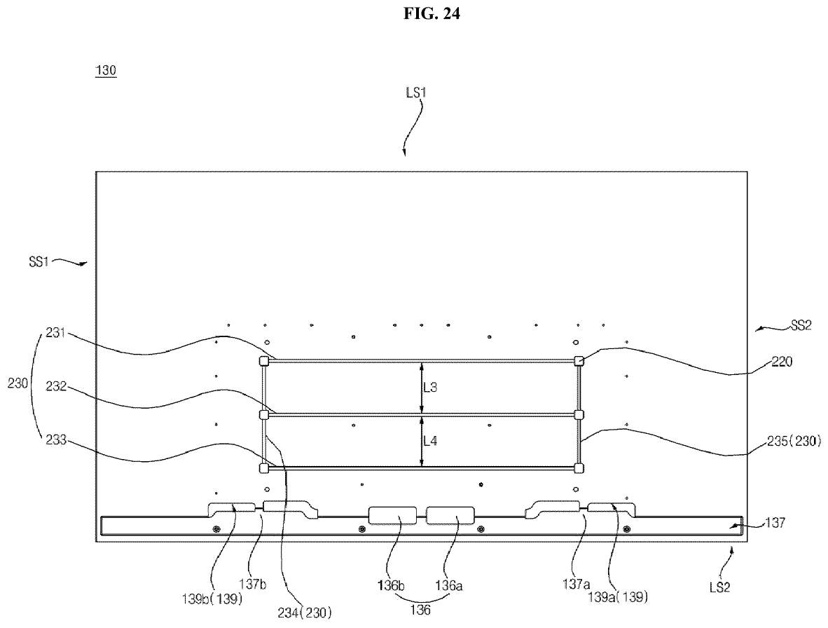

The rear inner line 230 may include a first rear horizontal line 231, a second rear horizontal line 232, a third rear horizontal line 233, a first rear vertical line 234, and a second rear vertical line 235 (see FIG. 24). The first rear horizontal line 234 may form the upper side of the rear inner line 230. The third rear horizontal line 233 may form the lower side of the rear inner line 230. The second rear horizontal line 232 may be located between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 (see FIG. 24) may connect the other end of the first rear horizontal line 231, the other end of the second rear horizontal line 232, and the other end of the third rear horizontal line 233. For example, a third distance L3 between the first rear horizontal line 231 and the second rear horizontal line 232 may be smaller than a fourth distance L4 between the second rear horizontal line 232 and the third rear horizontal line 233.

The node hole 220 may be formed at a point where the rear horizontal line 231, 232, 233 and the rear vertical line 234 and 235 meet. The node hole 220 may be formed by penetrating the front skin 132, core 131, and rear skin 133 of the material complexed panel 130. The length of the rear inner line 230 may be shorter than the length of the PCB plate 150. The width of the rear inner line 230 may be smaller than the width of the PCB plate 150. The PCB plate 150 may cover the rear inner line 230. Accordingly, the bending rigidity and/or torsional rigidity of the material complexed panel 130 may be improved.

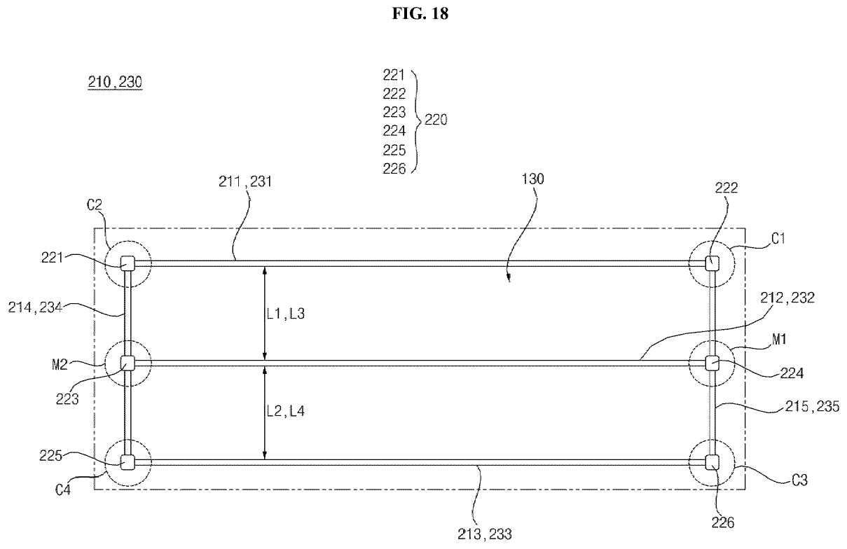

Referring to FIG. 18, there may be a plurality of node holes 220. The plurality of node holes 220 may include a first node hole 221, a second node hole 222, a third node hole 223, a fourth node hole 224, a fifth node hole 225, and a sixth node hole 226.

The first node hole 221 may be located at a corner C2 formed by the first horizontal line 211, 231 and the first vertical line 214, 234. The first node hole 221 may be formed by penetrating the material complexed panel 130 at the corner C2 of the first horizontal line 211, 231 and the first vertical line 214, 234.

The second node hole 222 may be located at the corner C1 formed by the first horizontal line 211, 231 and the second vertical line 212, 232. The second node hole 222 may be formed by penetrating the material complexed panel 130 at the corner C1 of the first horizontal line 211, 231 and the second vertical line 212, 232.

The third node hole 223 may be located at a node M2 formed by the second horizontal line 212, 232 and the first vertical line 214, 234. The third node hole 223 may be formed by penetrating the material complexed panel 130 at the node M2 of the second horizontal line 212, 232 and the first vertical line 214, 234.

The fourth node hole 224 may be located at a node M1 formed by the second horizontal line 212, 232 and the second vertical line 212, 232. The fourth node hole 224 may be formed by penetrating the material complexed panel 130 at the node M1 of the second horizontal line 212, 232 and the second vertical line 212, 232.

The fifth node hole 225 may be located at the corner C4 formed by the third horizontal line 213, 233 and the first vertical line 214, 234. The fifth node hole 225 may be formed by penetrating the material complexed panel 130 at the corner C4 of the third horizontal line 213, 233 and the first vertical line 214, 234.

The sixth node hole 226 may be located at the corner C3 formed by the third horizontal line 213, 233 and the second vertical line 212, 232. The sixth node hole 226 may be formed by penetrating the material complexed panel 130 at the corner C3 of the third horizontal line 213, 233 and the second vertical line 212, 232.

Accordingly, it is possible not only to improve the bending rigidity and/or torsional rigidity of the material complexed panel 130, but also to improve the flatness of the display panel 110 coupled to the material complexed panel 130.

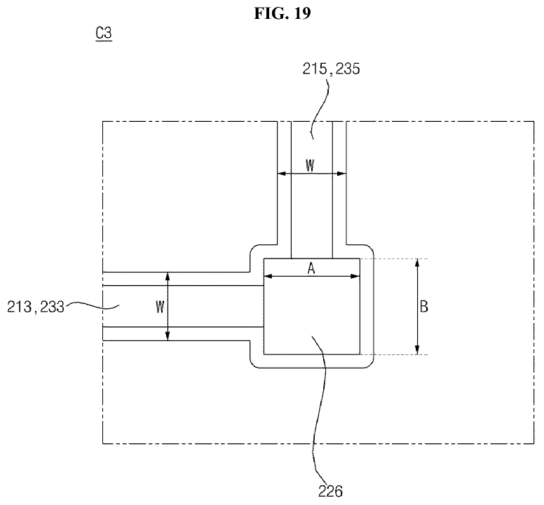

Referring to FIG. 19, the size of the sixth node hole 226 may be larger than the width of the third horizontal line 213, 233 and/or the second vertical line 215, 235. For example, when the sixth node hole 226 is quadrangle, the width A, B of the sixth node hole 226 may be larger than the width W of the third horizontal line 213, 233 and/or the second vertical line 215, 235. For another example, when the sixth node hole 226 is circular, the diameter of the sixth node hole 226 may be larger than the width of the third horizontal line 213, 233 and/or the second vertical line 215, 235. The description of the sixth node hole 226 may be applied to the first node hole 221, the second node hole 222, and/or the fifth node hole 225.

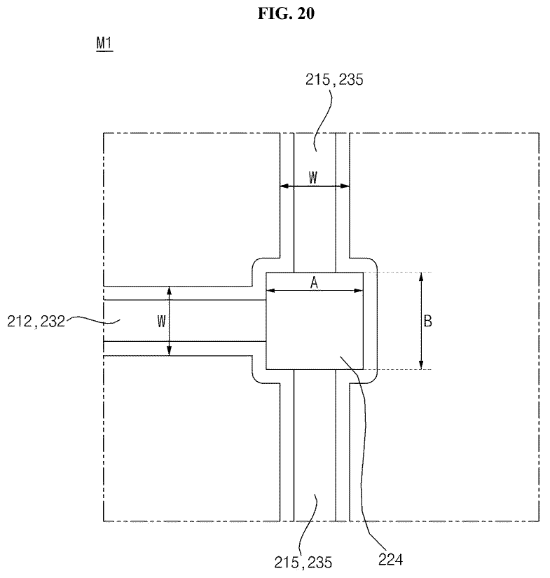

Referring to FIG. 20, the size of the fourth node hole 224 may be larger than the width of the second horizontal line 212, 232 and/or the second vertical line 215, 235. For example, when the fourth node hole 224 is quadrangle, the width A, B of the fourth node hole 224 may be larger than the width of the second horizontal line 212, 232 and/or the second vertical line 215, 235. For another example, when the fourth node hole 224 is circular, the diameter of the fourth node hole 224 may be larger than the width of the second horizontal line 212, 232 and/or the second vertical line 215, 235. The description of the fourth node hole 224 may also be applied to the third node hole 223.

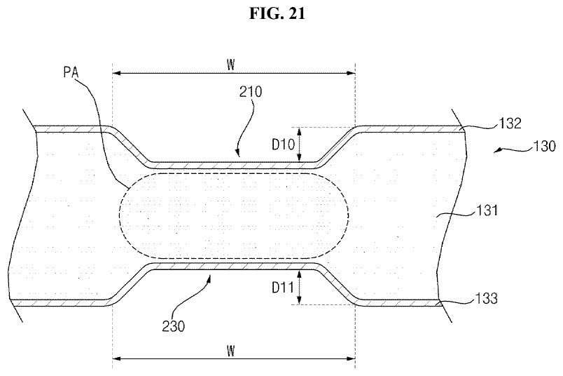

Referring to FIG. 21, the front inner line 210 may be formed in the material complexed panel 130 by compressing the core 131 and causing the front skin 132 to sink. The rear inner line 230 may be formed in the material complexed panel 130 by compressing the core 131 and causing the rear skin 133 to sink.

The front inner line 210 and the rear inner line 230 may be symmetrical with respect to the core 131. For example, the width W of the front inner line 210 may be substantially equal to the width W of the rear inner line 230. For another example, the depth D10 of the front inner line 210 may be substantially equal to the depth D11 of the rear inner line 230.

A pressed area PA in which the core 131 is compressed may be formed between the front inner line 210 and the rear inner line 230. The density of the core 131 in the pressed area PA may be greater than the density of the core 131 in a non-pressed area.

Accordingly, the bending rigidity and/or torsional rigidity of the material complexed panel 130 may be improved.

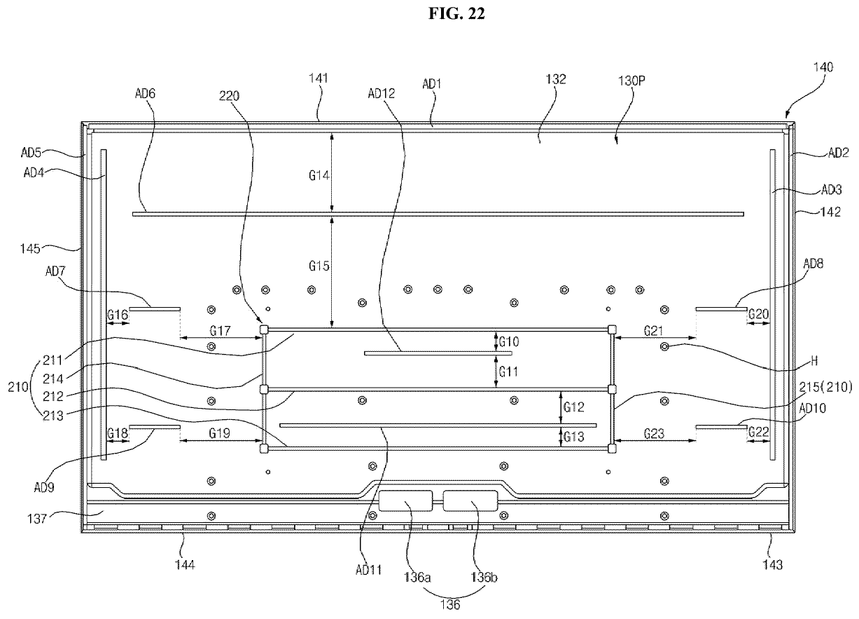

Referring to FIG. 22, the adhesive member AD may be disposed in the flat portion 130P of the material complexed panel 130. The adhesive member AD may be adhered to the front skin 132 of the material complexed panel 130. There may be a plurality of adhesive members AD.

A first adhesive member AD1 may be fixed to the first part 141 of the side frame 140. The first adhesive member AD1 may extend long along the longitudinal direction of the first part 141 of the side frame 140. A second adhesive member AD2 may extend long along the longitudinal direction of the second part 142 of the side frame 140, and may be fixed to the second part 142. A third adhesive member AD3 may extend long along the second part 142 of the side frame 140, be parallel to the second part 142, and be spaced apart from the first adhesive member AD1 to be fixed to the flat portion 130P.

A fifth adhesive member AD5 may extend long along the longitudinal direction of the fifth part 145 of the side frame 140, and may be fixed to the fifth part 145. A fourth adhesive member AD4 may extend long along the fifth part 145 of the side frame 140, be parallel to the fifth part 145, and be spaced apart from the fifth adhesive member AD5 to be fixed to the flat portion 130P.

A sixth adhesive member AD6 may extend long along the longitudinal direction of the first part 141 of the side frame 140, and may be fixed to the flat portion 130P while being spaced apart from the first adhesive member AD1. A fourteenth distance G14 from the first part 141 of the side frame 140 to the sixth adhesive member AD6 may be shorter than a fifteenth distance G15 from the sixth adhesive member AD6 to the first front horizontal inner line 211.

A seventh adhesive member AD7 may extend along the longitudinal direction of the sixth adhesive member AD6, and may be fixed to the flat portion 130P at between the first front vertical line 214 and the fourth adhesive member AD4. The seventh adhesive member AD7 may be located between the sixth adhesive member AD6 and a ninth adhesive member AD9. A sixteenth distance G16 from the fourth adhesive member AD4 to one distal end of the seventh adhesive member AD7 may be shorter than a seventeenth distance G17 from the first front vertical line 214 to the other distal end of the seventh adhesive member AD7.

The ninth adhesive member AD9 may extend along the longitudinal direction of the sixth adhesive member AD6, and may be fixed to the flat portion 130P at between the first front vertical line 214 and the fourth adhesive member AD4. The ninth adhesive member AD9 may be located between the seventh adhesive member AD7 and the receiving portion 137. An eighteenth distance G18 from the fourth adhesive member AD4 to one distal end of the ninth adhesive member AD9 may be shorter than a nineteenth distance G19 from the first front vertical line 214 to the other distal end of the ninth adhesive member AD9.

An eighth adhesive member AD8 may extend along the longitudinal direction of the sixth adhesive member AD6, and may be fixed to the flat portion 130P between the second front vertical line 215 and the third adhesive member AD3. The eighth adhesive member AD8 may be located between the sixth adhesive member AD6 and the receiving portion 137. A twentieth distance G20 from the third adhesive member AD3 to one distal end of the eighth adhesive member AD8 may be shorter than a twenty-first distance G21 from the second front vertical line 215 to the other distal end of the eighth adhesive member AD8.

A tenth adhesive member AD10 may extend along the longitudinal direction of the sixth adhesive member AD6, and may be fixed to the flat portion 130P at between the second front vertical line 215 and the third adhesive member AD3. The tenth adhesive member AD10 may be located between the eighth adhesive member AD8 and the receiving portion 137. A twenty-second distance G22 from the third adhesive member AD3 to one distal end of the tenth adhesive member AD10 may be shorter than a twenty-third distance G23 from the second front vertical line 215 to the other distal end of the tenth adhesive member AD10.

An eleventh adhesive member AD11 may extend long along the longitudinal direction of the second front horizontal line 212, and be fixed to the flat portion 130P at between the second front horizontal line 212 and the third front horizontal line 213. A twelfth adhesive member AD12 may extend long along the longitudinal direction of the second front horizontal line 212, and may be located between the first front horizontal line 211 and the second front horizontal line 212. The length of the twelfth adhesive member AD12 may be shorter than the length of the eleventh adhesive member AD11.

A tenth distance G10 between the first front horizontal line 211 and the twelfth adhesive member AD12 may be shorter than an eleventh distance G11 between the twelfth adhesive member AD12 and the second front horizontal line 212. For example, the tenth distance G10 may be 40 millimeters or more. For example, the distance between one distal end of the twelfth adhesive member AD12 and the first vertical front line 214 may be 20 mm or more. For another example, the distance between the other distal end of the twelfth adhesive member AD12 and the second vertical front line 215 may be 20 mm or more.

A twelfth distance G12 between the second front horizontal line 212 and the eleventh adhesive member AD11 may be longer than a thirteenth distance G13 between the eleventh adhesive member AD11 and the third front horizontal line 213. For example, the thirteenth distance G13 may be 40 millimeters or more.

The display panel 110 may be coupled to or fixed to the material complexed panel 130 by the adhesive member AD. Accordingly, the display panel 110 may be flatly fixed to the material complexed panel 130.

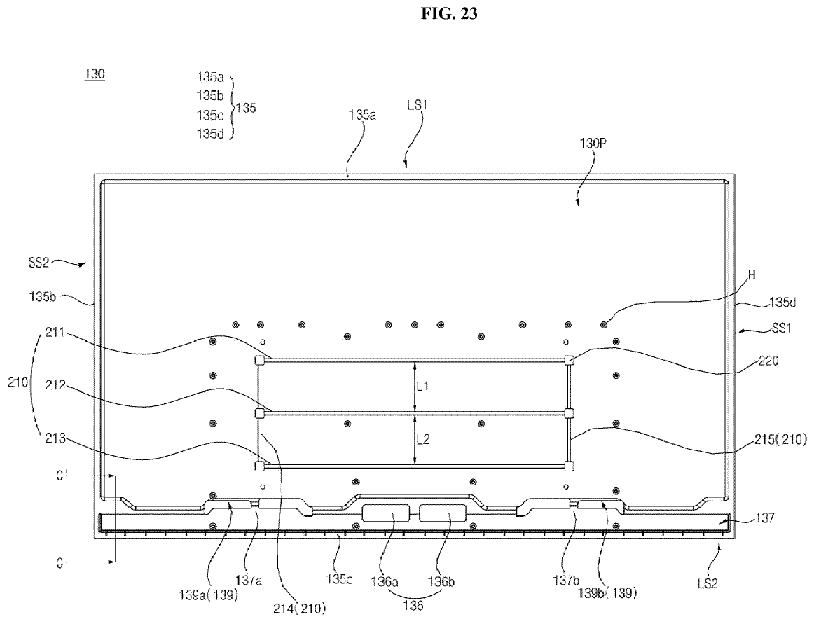

Referring to FIGS. 23 and 24, the material complexed panel 130 may include the flat portion 130P, the receiving portion 137, and the outer part 135. The outer part 135 may be formed around the flat portion 130P, and may form the edge of the material complexed panel 130. The first outer part 135a may be formed along the upper side of the flat portion 130P, the second outer part 135b may be formed along the left side of the flat portion 130P, the third outer part 135c may be formed along the lower side of the flat portion 130P, and the fourth outer part 135d may be formed along the right side of the flat portion 130P. The outer part 135 may be formed by pressing the flat portion 130P. The outer part 135 may form a step as it is lowered from the flat portion 130P. The thickness of the flat portion 130P may be greater than the thickness of the outer part 135. The lower side of the flat portion 130P may form a curved line.

The receiving portion 137 may be formed in the third outer part 135c while being adjacent to the lower side of the flat portion 130P. There may be a plurality of receiving portions 137. The first receiving portion 137a may be located between the first cable hole 136a and the second short side SS2. The second receiving portion 137b may be located between the second cable hole 136b and the first short side SS1. The first receiving portion 137a may be connected to the second receiving portion 137b. The receiving portion 137 may be formed by pressing the third outer part 135c from the front to the rear. The receiving portion 137 may form a step that is lowered from the front surface of the outer part 135c.

The cable hole 136 may be formed to penetrate the front skin 132 (see FIG. 2) and the rear skin 133 (see FIG. 2) of the receiving portion 137. The cable hole 136 may be formed in the receiving portion 137 and/or the third outer part 135c while being adjacent to the lower side of the flat portion 130P. There may be a plurality of cable holes 136. A first cable hole 136a may be located adjacent to a second cable hole 136b.

The inner frame 210, 230 may be formed on the front surface and/or rear surface of the material complexed panel 130. The inner frame 210, 230 may be referred to as a pressed frame 210, 230 or a rigid line 210, 230. The inner frame 210, 230 may be formed by sinking the front skin 132 and/or rear skin 133 of the material complexed panel 130 and compressing the core 131 (see FIG. 2).

The inner frame 210, 230 may include the front inner line 210, the rear inner line 230, and the node hole 220. The front inner line 210 may be formed by sinking the front skin 132 of the material complexed panel 130. The rear inner line 230 may be formed by sinking the rear skin 133 of the material complexed panel 130.

The front inner line 210 may include a first front horizontal line 211, a second front horizontal line 212, a third front horizontal line 213, a first front vertical line 214, and a second front vertical line 215. The first front horizontal line 214 may form the upper side of the front inner line 210. The third front horizontal line 213 may form the lower side of the front inner line 210. The second front horizontal line 212 may be located between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213. For example, the first distance L1 between the first front horizontal line 211 and the second front horizontal line 212 may be smaller than the second distance L2 between the second front horizontal line 212 and the third front horizontal line 213.

The node hole 220 may be formed at a point where the front horizontal line 211, 212, 213 and the front vertical line 214, 215 meet. The node hole 220 may be formed by penetrating the front skin 132, core 131, and rear skin 133 of the material complexed panel 130.

The rear inner line 230 may include the first rear horizontal line 231, the second rear horizontal line 232, the third rear horizontal line 233, the first rear vertical line 234, and the second rear vertical line 235. The first rear horizontal line 231 may form the upper side of the rear inner line 230. The third rear horizontal line 233 may form the lower side of the rear inner line 230. The second rear horizontal line 232 may be located between the first rear horizontal line 231 and the third rear horizontal line 233. The first rear vertical line 234 may connect one end of the first rear horizontal line 231, one end of the second rear horizontal line 232, and one end of the third rear horizontal line 233. The second rear vertical line 235 may connect the other end of the first rear horizontal line 231, the other end of the second rear horizontal line 232, and the other end of the third rear horizontal line 233. For example, the third distance L3 between the first rear horizontal line 231 and the second rear horizontal line 232 may be smaller than the fourth distance L4 between the second rear horizontal line 232 and the third rear horizontal line 233.

The node hole 220 may be formed at a point where the rear horizontal line 231, 232, 233 and the rear vertical line 234 and 235 meet. The node hole 220 may be formed by penetrating the front skin 132, core 131, and rear skin 133 of the material complexed panel 130.

The receiving portion 137 may be formed by pressing the third outer part 135c from the front to the rear. The receiving portion 137 may form a step that is raised from the rear surface of the third outer part 135c.

A cut-out portion 139 may be formed in at least a portion of a bending line formed along the lower side of the flat portion 130P. There may be a plurality of cut-out portions 139. A first cut-portion 139a may be aligned with the first receiving portion 137a, and a second cut-out portion 139b may be aligned with the second receiving portion 137b. The cut-out portion 139 may be formed in a line forming a step between the front surface of the flat portion 130P and the third outer part 135c. The cut-out portion 139 may be formed in a line where the third outer part 135c and the receiving portion 137 form a step.

Accordingly, it is possible not only to improve the bending rigidity and/or torsional rigidity of the material complexed panel 130, but also to improve the flatness of the material complexed panel 130.

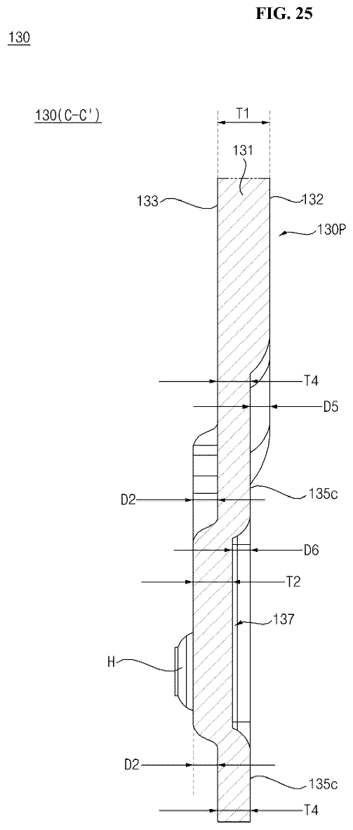

Referring to FIG. 25, the third outer part 135c may be formed by pressing the flat portion 130P. The front skin 132 of the third outer part 135c may form a step D5 that is lowered from the front skin 132 of the flat portion 130P.

The receiving portion 137 may be formed by pressing the third outer part 135c. The front skin 132 of the receiving portion 137 may form a step D6 that is lowered from the front skin 132 of the third outer part 135c.

The rear skin 133 of the receiving portion 137 may form a step D2 that is raised from the rear skin 133 of the third outer part 135c. For example, the height of the step D6 lowered from the front skin 132 of the third outer part 135c to the front skin 132 of the receiving portion 137 may be smaller than the height of the step D2 that is raised from the rear skin 133 of the third outer part 135c to the rear skin 133 of the receiving portion 137. The thickness T1 of the flat portion 130P may be greater than the thickness T2 of the receiving portion 137. The thickness T4 of the third outer part 135c may be smaller than the thickness T1 of the flat portion 130P. The thickness T2 of the receiving portion 137 may be greater than the thickness T4 of the third outer part 135c.

The core 131 of the material complexed panel 130 may absorb external force as it is pressed in the direction from the front skin 132 of the flat portion 130P to the rear skin 133. The magnitude of the external force applied to the front skin 132 of the flat portion 130P may be greater than the magnitude of the external force applied to the rear skin 133 of the flat portion 130P. The core 131 of the material complexed panel 130 may not only secure rigidity but also absorb shock.

The fastening groove H may protrude from the rear skin 133 of the receiving portion 137. The fastening groove H may be recessed in the front skin 132 of the receiving portion 137, and protrude from the rear skin 133 of the receiving portion 137. The center of the fastening groove H may be penetrated.

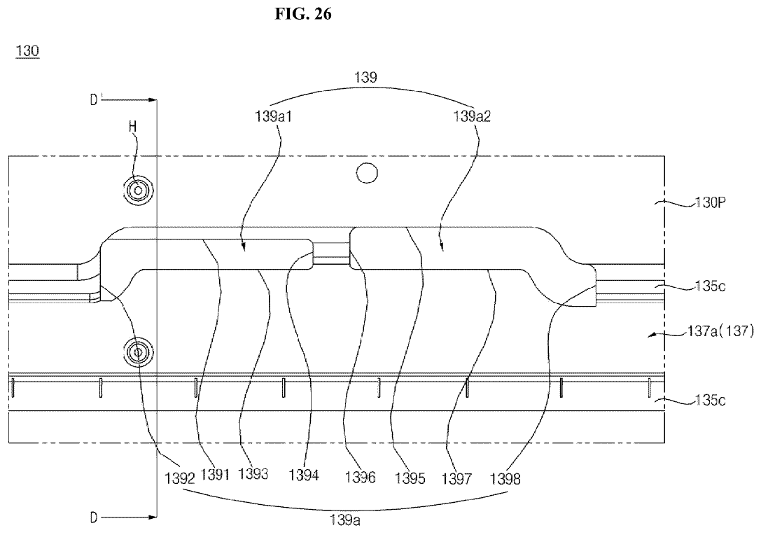

Referring to FIG. 26, the first-cut-out portion 139a may include a first slit 139al and a second slit 139a2. The first slit 139al and/or the second slit 139a2 may extend long in the longitudinal direction of the receiving portion 137. The first slit 139al may be formed in the boundary of the flat portion 130P, the boundary of the third outer part 135c, and/or the boundary of the first receiving portion 137a. The second slit 139a2 may be adjacent to the first slit 139al, and may be formed in the boundary of the flat portion 130P, the boundary of the third outer part 135c, and/or the boundary of the first receiving portion 137a.

The first slit 139al may include an upper side 1391, a left side 1392, a right side 1394, and a lower side 1393. The upper side 1391 may be formed in a step area formed in the lower boundary of the flat portion 130P. The lower side 1393 may be formed in the first receiving portion 137a while being adjacent to the upper side of the first receiving portion 137a. The left side 1392 may connect the left distal end of the upper side 1391 and the left distal end of the lower side 1393, and be formed in the step area of lower side of the flat portion 130P, the third outer part 135c, and/or the first receiving portion 137a. The right side 1394 may be formed in a step area formed in the boundary of the lower side 1393 of the flat portion 130P, the third outer part 135c, and/or the first receiving portion 137a. For example, the length of the left side 1392 may be greater than the length of the right side 1394, the upper side 1391 may form a straight line, and the lower side 1393 may include a straight line and a curved line.

The second slit 139a2 may include an upper side 1395, a left side 1396, a right side 1398, and a lower side 1397. The upper side 1395 may be formed in the lower boundary of the flat portion 130P. The lower side 1397 may be formed in the first receiving portion 137a while being adjacent to the upper side of the first receiving portion 137a. The left side 1396 may connect the left distal end of the upper side 1395 and the left distal end of the lower side 1397, and be formed in the step area of lower side of the flat portion 130P, the third outer part 135c, and/or the first receiving portion 137a. The right side 1398 may be formed in the step area formed in the lower boundary of the flat portion 130P, the third outer part 135c, and/or the first receiving portion 137a. For example, the length of the left side 1396 may be substantially equal to the length of the right side 1398, the upper side 1395 may include a straight line and a curved line, and the lower side 1397 may include a straight line and a curved line. The upper side 1395 may be parallel to the lower side 1397.

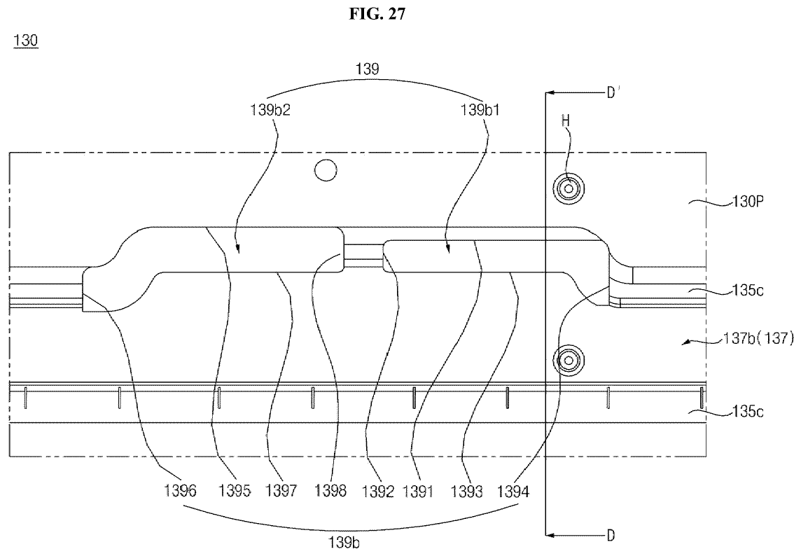

Referring to FIG. 27, the second cut-out portion 139b may include a first slit 139b1 and a second slit 139b2. The first slit 139b1 and/or the second slit 139b2 may extend long in the longitudinal direction of the receiving portion 137. The first slit 139b1 may be formed in the boundary of the flat portion 130P, the boundary of the third outer part 135c, and/or the boundary of the second receiving portion 137b. The second slit 139b2 may be adjacent to the first slit 139b1, and may be formed in the boundary of the flat portion 130P, the boundary of the third outer part 135c, and/or the boundary of the second receiving portion 137b.

The first slit 139b1 may include the upper side 1391, the left side 1392, the right side 1394, and the lower side 1393. The upper side 1391 may be formed in a step area formed in the lower boundary of the flat portion 130P. The lower side 1393 may be formed in the second receiving portion 137b while being adjacent to the upper side of the second receiving portion 137b. The left side 1392 may connect the left distal end of the upper side 1391 and the left distal end of the lower side 1393, and be formed in the step area of lower side of the flat portion 130P, the third outer part 135c, and/or the second receiving portion 137b. The right side 1394 may be formed in a step area formed in the boundary of the lower side 1393 of the flat portion 130P, the third outer part 135c, and/or the second receiving portion 137b. For example, the length of the left side 1392 may be greater than the length of the right side 1394, the upper side 1391 may form a straight line, and the lower side 1393 may include a straight line and a curved line.

The second slit 139b2 may include the upper side 1395, the left side 1396, the right side 1398, and the lower side 1397. The upper side 1395 may be formed in the lower boundary of the flat portion 130P. The lower side 1397 may be formed in the second receiving portion 137b while being adjacent to the upper side of the second receiving portion 137b. The left side 1396 may connect the left distal end of the upper side 1395 and the left distal end of the lower side 1397, and be formed in the step area of lower side of the flat portion 130P, the third outer part 135c, and/or the second receiving portion 137b. The right side 1398 may be formed in the step area formed in the lower boundary of the flat portion 130P, the third outer part 135c, and/or the second receiving portion 137b. For example, the length of the left side 1396 may be substantially equal to the length of the right side 1398, the upper side 1395 may include a straight line and a curved line, and the lower side 1397 may include a straight line and a curved line. The upper side 1395 may be parallel to the lower side 1397.

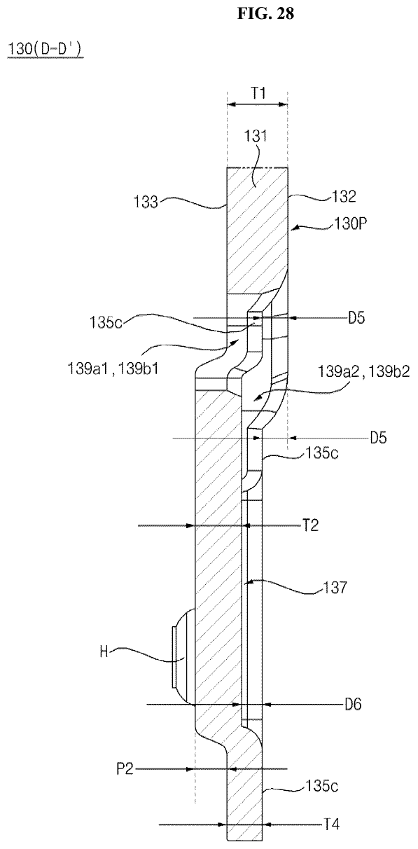

Referring to FIG. 28, the third outer part 135c may be formed by pressing the flat portion 130P. The front skin 132 of the third outer part 135c may form a step D5 that is lowered from the front skin 132 of the flat portion 130P.

The receiving portion 137 may be formed by pressing the third outer part 135c. The front skin 132 of the receiving portion 137 may form a step D6 that is lowered from the front skin 132 of the third outer part 135c.

The rear skin 133 of the receiving portion 137 may form a step D2 that is raised from the rear skin 133 of the third outer part 135c. For example, the height of the step D6 lowered from the front skin 132 of the third outer part 135c to the front skin 132 of the receiving portion 137 may be smaller than the height of the step D2 that is raised from the rear skin 133 of the third outer part 135c to the rear skin 133 of the receiving portion 137. The thickness T1 of the flat portion 130P may be greater than the thickness T2 of the receiving portion 137. The thickness T4 of the third outer part 135c may be smaller than the thickness T1 of the flat portion 130P. The thickness T2 of the receiving portion 137 may be greater than the thickness T4 of the third outer part 135c.

The core 131 of the material complexed panel 130 may absorb external force as it is pressed in the direction from the front skin 132 of the flat portion 130P to the rear skin 133. The magnitude of the external force applied to the front skin 132 of the flat portion 130P may be greater than the magnitude of the external force applied to the rear skin 133 of the flat portion 130P. The core 131 of the material complexed panel 130 may not only secure rigidity but also absorb shock.

The fastening groove H may protrude from the rear skin 133 of the receiving portion 137. The fastening groove H may be recessed in the front skin 132 of the receiving portion 137, and protrude from the rear skin 133 of the receiving portion 137. The center of the fastening groove H may be penetrated.

The first slit 139a1, 139b1 may be formed to penetrate the front skin 132, the core 131, and/or the rear skin 133. The second slit 139a2, 139b2 may be formed to penetrate the front skin 132, the core 131, and/or the rear skin 133.

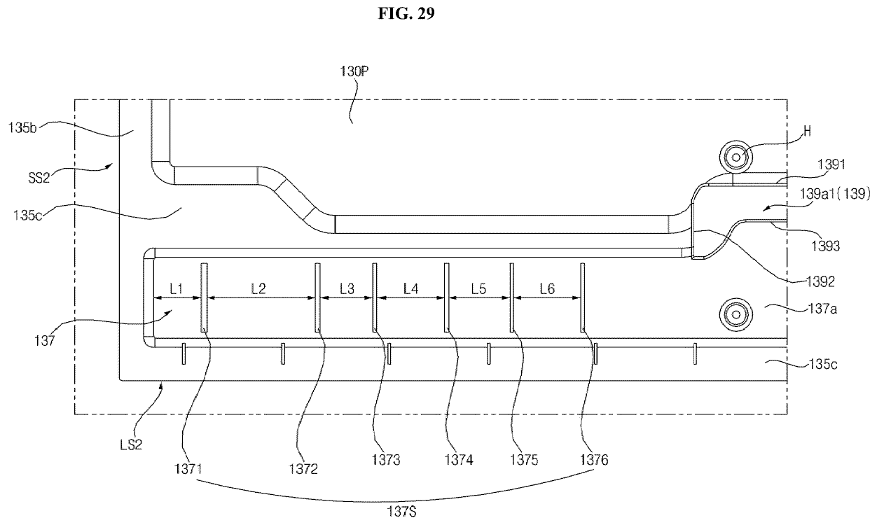

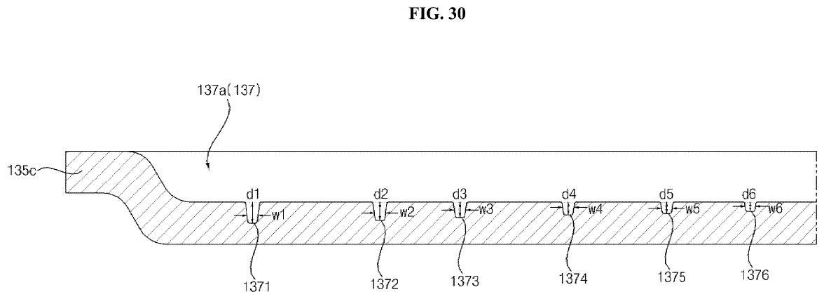

Referring to FIGS. 29 and 30, a slit groove 137s may be formed on the receiving portion 137, 137a. The slit groove 137s may extend long in the width direction of the receiving portion 137. The slit groove 137s may be formed by sinking the front skin 132 (see FIG. 28) of the receiving portion 137. The slit groove 137s may be formed by pressing the front skin 132 of the receiving portion 137. There may be a plurality of slit grooves 137s. The slit groove 137s may be referred to as a press line 137s, a press slit 137s, a vertical line 137s, or a vertical slit 137s.

A first slit groove 1371 may extend in the width direction of the receiving portion 137, and may be formed in the receiving portion 137 by being disposed to be closest to the second short side SS2 among the plurality of slit grooves 137s. A second slit groove 1372 may be formed in the receiving portion 137 by being disposed between the first slit 139al and the first slit groove 1371. A third slit groove 1373 may be formed in the receiving portion 137 by being disposed between the second slit groove 1372 and the first slit 139a1. A fourth slit groove 1374 may be formed in the receiving portion 137 by being disposed between the third slit groove 1373 and the first slit 139a1. A fifth slit groove 1375 may be formed in the receiving portion 137 by being disposed between the fourth slit groove 1374 and the first slit 139al. A sixth slit groove 1376 may be formed in the receiving portion 137 by being disposed between the fifth slit groove 1375 and the first slit 139a1. The lengths of the slit grooves 137s may be substantially the same.

The first distance L1 between a distal end step of the receiving portion 137 adjacent to the second short side SS2 and the first slit groove 1371 may be smaller than a second distance L2 between the first slit groove 1371 and the second slit groove 1372. For example, the first distance L1 may be about 3 centimeters, and the second distance L2 may be about 5 centimeters. The third distance L3 between the second slit groove 1372 and the third slit groove 1373 may be smaller than the first distance L1. For example, the third distance L3 may be about 2 centimeters.

The fourth distance L4 between the third slit groove 1373 and the fourth slit groove 1374 may be greater than the third distance L3, and may be substantially equal to the first distance L1. For example, the fourth distance L4 may be about 3 centimeters.

A fifth distance L5 between the fourth slit groove 1374 and the fifth slit groove 1375 may be greater than the third distance L3, and smaller than the fourth distance L4. For example, the fifth distance L5 may be about 2.5 centimeters.

A sixth distance L6 between the fifth slit groove 1375 and the sixth slit groove 1376 may be substantially equal to the fifth distance L5. For example, the sixth distance L6 may be about 2.5 centimeters.

The width W1 and/or depth d1 of the first slit groove 1371 may be greater than the width W2 and/or depth d2 of the second slit groove 1372. The width W2 and/or depth d2 of the second slit groove 1372 may be greater than the width W3 and/or depth d3 of the third slit groove 1373. The width W3 and/or depth d3 of the third slit groove 1373 may be greater than the width W4 and/or depth d4 of the fourth slit groove 1374. The width W4 and/or depth d4 of the fourth slit groove 1374 may be greater than the width W5 and/or depth d5 of the fifth slit groove 1375. The width W5 and/or depth d5 of the fifth slit groove 1375 may be greater than the width W6 and/or depth d6 of the sixth slit groove 1376.

The receiving portion 137 formed by pressing the third outer part 135c may not secure a flatness as the core 131 of the material complexed panel 130 absorbs a press shock. The slit grooves 137s may improve the flatness of the receiving portion 137.

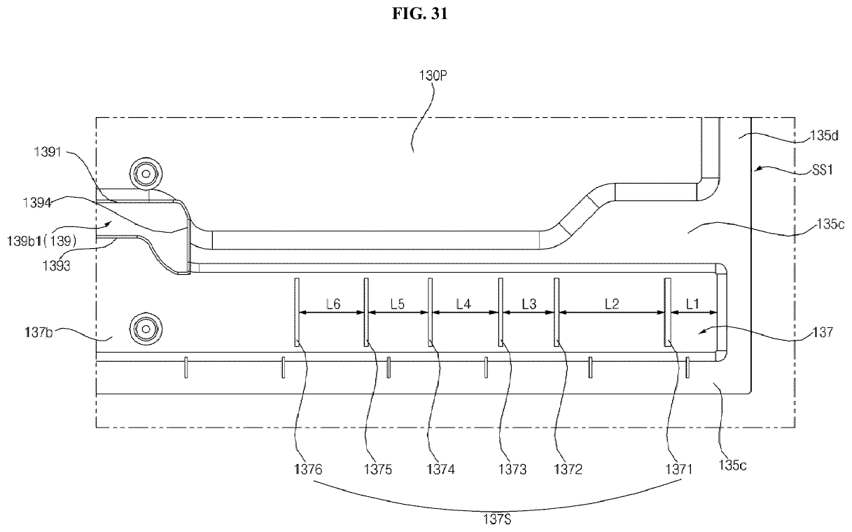

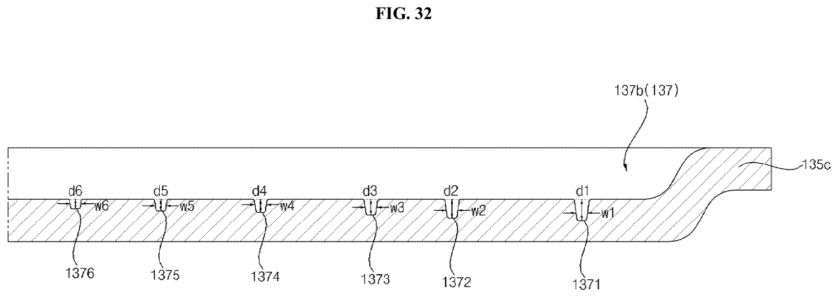

Referring to FIGS. 31 and 32, slit groove 137s may be formed on the receiving portion 137, 137b. The slit groove 137s may extend long in the width direction of the receiving portion 137. The slit groove 137s may be formed by sinking the front skin 132 (see FIG. 28) of the receiving portion 137. The slit groove 137s may be formed by pressing the front skin 132 of the receiving portion 137. There may be a plurality of slit grooves 137s. The slit groove 137s may be referred to as a press line 137s, a press slit 137s, a vertical line 137s, or a vertical slit 137s.

The first slit groove 1371 may extend in the width direction of the receiving portion 137, and may be formed in the receiving portion 137 by being disposed to be closest to the first short side SS1 among the plurality of slit grooves 137s. The second slit groove 1372 may be formed in the receiving portion 137 by being disposed between the first slit 139b1 and the first slit groove 1371. The third slit groove 1373 may be formed in the receiving portion 137 by being disposed between the second slit groove 1372 and the first slit 139b1. The fourth slit groove 1374 may be formed in the receiving portion 137 by being disposed between the third slit groove 1373 and the first slit 139b1. The fifth slit groove 1375 may be formed in the receiving portion 137 by being disposed between the fourth slit groove 1374 and the first slit 139b1. The sixth slit groove 1376 may be formed in the receiving portion 137 by being disposed between the fifth slit groove 1375 and the first slit 139b1. The lengths of the slit grooves 137s may be substantially the same.

The first distance L1 between a distal end step of the receiving portion 137 adjacent to the first short side SS1 and the first slit groove 1371 may be smaller than a second distance L2 between the first slit groove 1371 and the second slit groove 1372. For example, the first distance L1 may be about 3 centimeters, and the second distance L2 may be about 5 centimeters.

The third distance L3 between the second slit groove 1372 and the third slit groove 1373 may be smaller than the first distance L1. For example, the third distance L3 may be about 2 centimeters.

The fourth distance L4 between the third slit groove 1373 and the fourth slit groove 1374 may be greater than the third distance L3, and may be substantially equal to the first distance L1. For example, the fourth distance L4 may be about 3 centimeters.

The fifth distance L5 between the fourth slit groove 1374 and the fifth slit groove 1375 may be greater than the third distance L3, and smaller than the fourth distance L4. For example, the fifth distance L5 may be about 2.5 centimeters.

The sixth distance L6 between the fifth slit groove 1375 and the sixth slit groove 1376 may be substantially equal to the fifth distance L5. For example, the sixth distance L6 may be about 2.5 centimeters.

The width W1 and/or depth d1 of the first slit groove 1371 may be greater than the width W2 and/or depth d2 of the second slit groove 1372. The width W2 and/or depth d2 of the second slit groove 1372 may be greater than the width W3 and/or depth d3 of the third slit groove 1373. The width W3 and/or depth d3 of the third slit groove 1373 may be greater than the width W4 and/or depth d4 of the fourth slit groove 1374. The width W4 and/or depth d4 of the fourth slit groove 1374 may be greater than the width W5 and/or depth d5 of the fifth slit groove 1375. The width W5 and/or depth d5 of the fifth slit groove 1375 may be greater than the width W6 and/or depth d6 of the sixth slit groove 1376.

The receiving portion 137 formed by pressing the third outer part 135c may not secure a flatness as the core 131 of the material complexed panel 130 absorbs a press shock. The slit grooves 137s may improve the flatness of the receiving portion 137.

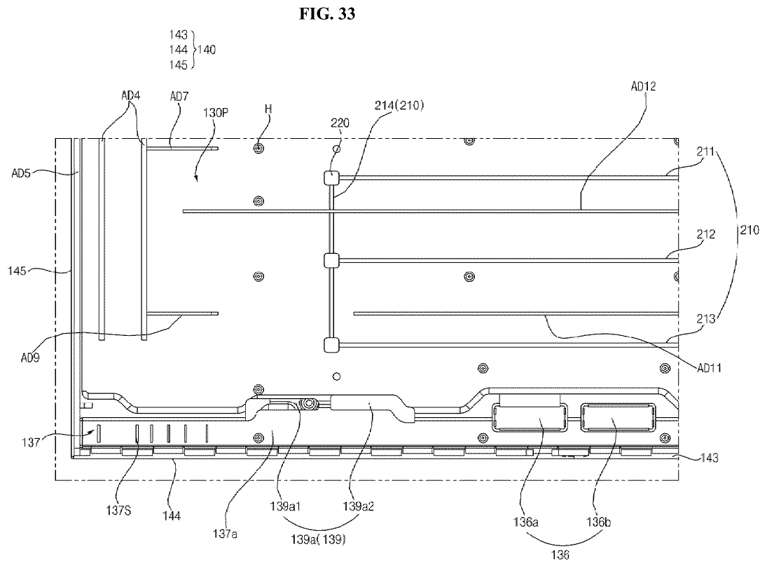

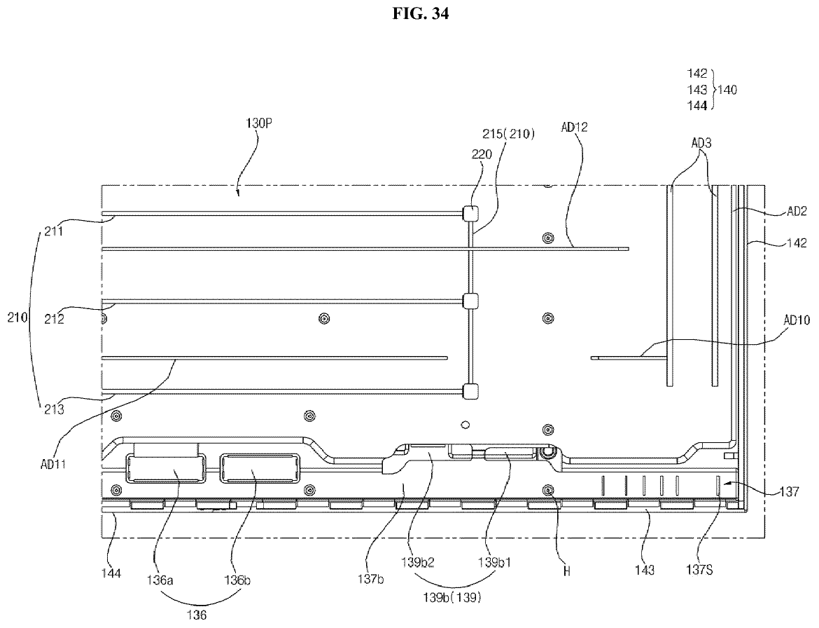

Referring to FIGS. 33 and 34, the side frame 140 may be coupled to the outer part 135 (see FIG. 23) while being adjacent to the flat portion 130P. The side frame 140 may include the first part 141 (see FIG. 16), the second part 142, the third part 143, the fourth part 144, and the fifth part 145.

The front inner line 210 may include the first front horizontal line 211, the second front horizontal line 212, the third front horizontal line 213, the first front vertical line 214, and the second front vertical line 215. The first front horizontal line 214 may form the upper side of the front inner line 210. The third front horizontal line 213 may form the lower side of the front inner line 210. The second front horizontal line 212 may be located between the first front horizontal line 211 and the third front horizontal line 213. The first front vertical line 214 may connect one end of the first front horizontal line 211, one end of the second front horizontal line 212, and one end of the third front horizontal line 213. The second front vertical line 215 may connect the other end of the first front horizontal line 211, the other end of the second front horizontal line 212, and the other end of the third front horizontal line 213.

The node hole 220 may be formed at a point where the front horizontal line 211, 212, 213 and the front vertical line 214, 215 meet. The node hole 220 may be formed by penetrating the front skin 132, core 131, and rear skin 133 of the material complexed panel 130.

The cut-out portion 139 may be formed in at least a portion of a bending line formed along the lower side of the flat portion 130P. There may be a plurality of cut-out portions 139. The first cut-portion 139a may be aligned with the first receiving portion 137a, and the second cut-out portion 139b may be aligned with the second receiving portion 137b. The cut-out portion 139 may be formed in a line forming a step between the front surface of the flat portion 130P and the third outer part 135c. The cut-out portion 139 may be formed in a line where the third outer part 135c and the receiving portion 137 form a step.

The slit groove 137s may be formed on the receiving portion 137. The slit groove 137s may extend long in the width direction of the receiving portion 137. The slit groove 137s may be formed by sinking the front skin 132 (see FIG. 28) of the receiving portion 137. The slit groove 137s may be formed by pressing the front skin 132 of the receiving portion 137. There may be a plurality of slit grooves 137s.

Accordingly, it is possible not only to improve the bending rigidity and/or torsional rigidity of the material complexed panel 130, but also to improve the flatness of the material complexed panel 130.

Referring to FIGS. 1 to 34, the display device includes a display panel; a material complexed plate located in a rear of the display panel; and a side frame which is located between the display panel and the material complexed plate, is fixed to the material complexed plate, and to which the display panel is coupled, wherein the material complexed plate includes: a front skin which forms a front surface; a rear skin which forms a rear surface and faces the front skin; and a core which is located between the front skin and the rear skin, and contains fibers, wherein the material complexed plate includes: a flat portion facing the display panel; an outer part which forms a circumference of the flat portion, and has a front surface where the front skin and the core are pressed to form a step lowered from a front surface of the flat portion; and a receiving portion which is formed in the outer part along a longitudinal direction of one side of the display panel, and has a front surface that forms a step lowered from a front surface of the outer part, wherein the receiving portion includes a plurality of slit grooves which extend in a direction intersecting the longitudinal direction of one side of the display panel, are sequentially spaced apart in the longitudinal direction of one side of the display panel, and are formed in a front surface of the receiving portion.

The plurality of slit grooves are formed in the receiving portion at different depths.

The material complexed plate includes a cable hole which is formed in at least a portion of the receiving portion, and penetrates the front skin, the core, and the rear skin, wherein the display panel includes: a first short side; and a second short side opposite to the first short side with respect to the one side, wherein the plurality of slit grooves include: a first slit groove which is located between the cable hole and the first short side, and closer to the first short side than the cable hole; and a second slit groove which is located between the cable hole and the first slit groove, and is closer to the first short side than the cable hole, wherein a first distance from a distal end of the receiving portion adjacent to the first short side to the first slit groove is smaller than a second distance from the first slit groove to the second slit groove.

The plurality of slit grooves further includes: a third slit groove located between the cable hole and the second slit groove; and a fourth slit groove located between the cable hole and the third slit groove, wherein a third distance from the second slit groove to the third slit groove is smaller than a fourth distance from the third slit groove to the fourth slit groove.

The plurality of slit grooves are formed by pressing a front skin of the receiving portion, and a depth of the first slit groove is greater than a depth of the second slit groove.

The depth of the second slit groove is greater than a depth of the third slit groove.

The plurality of slit grooves are formed by pressing the front skin of the receiving portion and the core.

The material complexed plate further includes a cut-out portion which is formed in at least a portion of a boundary between the flat portion and the outer part along the longitudinal direction of one side of the display panel, wherein the cut-out portion is formed by penetrating the front skin, the core, and the rear skin.

The material complexed plate includes a cable hole which is formed in at least a portion of the receiving portion, and formed to penetrate the front skin, the core, and the rear skin, wherein the cut-out portion is located between the cable hole and the plurality of slit grooves.

The cut-out portion includes: a first slit located between the cable hole and the plurality of slit grooves; and a second slit which is located between the cable hole and the first slit, and spaced apart from the first slit, wherein a width of the first slit is smaller than a width of the second slit.

The cut-out portion is formed in at least a portion of a boundary between the outer part and the receiving portion.

A thickness of the flat portion is larger than a thickness of the receiving portion.

The effects of the display device according to this disclosure are described as follows.

According to at least one of the embodiments of the present disclosure, structural rigidity of a large screen ultra-thin display device can be ensured.

According to at least one of the embodiments of the present disclosure, structural stability of a display device can be ensured.

According to at least one of the embodiments of the present disclosure, the flatness of the frame of the display device can be improved.

Certain embodiments or other embodiments of the invention described above are not mutually exclusive or distinct from each other. Any or all elements of the embodiments of the invention described above may be combined or combined with each other in configuration or function.

For example, a configuration “A” described in one embodiment of the invention and the drawings and a configuration “B” described in another embodiment of the invention and the drawings may be combined with each other. Namely, although the combination between the configurations is not directly described, the combination is possible except in the case where it is described that the combination is impossible

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a material complexed plate located in a rear of the display panel; and
a side frame fixed to the material complexed plate, the display panel coupled with the side frame or the material complexed plate,
wherein the material complexed plate comprises:
a front skin forming a front surface;
a rear skin forming a rear surface and facing the front skin; and
a core located between the front skin and the rear skin, and including fibers,
wherein the material complexed plate comprises:
a flat portion facing the display panel;
an outer part forming a circumference of the flat portion, wherein the front skin and the core of the outer part are pressed such that a front surface of the outer part is stepped down from a front surface of the flat portion; and
a receiving portion formed in the outer part along a longitudinal direction of one side of the display panel, and including a front surface stepped down from the front surface of the outer part,
wherein the receiving portion comprises a plurality of slit grooves extending in a direction intersecting the longitudinal direction of one side of the display panel, the plurality of slit grooves sequentially spaced apart in the longitudinal direction of one side of the display panel and formed in the front surface of the receiving portion.

2. The display device of claim 1, wherein the plurality of slit grooves is formed in the receiving portion at different depths.

3. The display device of claim 1, wherein the material complexed plate comprises a cable hole formed in at least a portion of the receiving portion and penetrating the front skin, the core, and the rear skin,
wherein the display panel comprises:
a first short side; and
a second short side opposite to the first short side with respect to the one side,
wherein the plurality of slit grooves comprises:
a first slit groove which is located between the cable hole and the first short side, and closer to the first short side than the cable hole; and
a second slit groove which is located between the cable hole and the first slit groove, and is closer to the first short side than the cable hole,
wherein a first distance from a distal end of the receiving portion adjacent to the first short side to the first slit groove is smaller than a second distance from the first slit groove to the second slit groove.

4. The display device of claim 3, wherein the plurality of slit grooves further comprises:
a third slit groove located between the cable hole and the second slit groove; and
a fourth slit groove located between the cable hole and the third slit groove,
wherein a third distance from the second slit groove to the third slit groove is smaller than a fourth distance from the third slit groove to the fourth slit groove.

5. The display device of claim 4, wherein the plurality of slit grooves is formed by pressing a front skin of the receiving portion, and
a depth of the first slit groove is greater than a depth of the second slit groove.

6. The display device of claim 5, wherein the depth of the second slit groove is greater than a depth of the third slit groove.

7. The display device of claim 5, wherein the plurality of slit grooves is formed by pressing the front skin of the receiving portion and the core.

8. The display device of claim 1, wherein the material complexed plate further comprises a cut-out portion which is formed in at least a portion of a boundary between the flat portion and the outer part along the longitudinal direction of one side of the display panel,
wherein the cut-out portion is formed by penetrating the front skin, the core, and the rear skin.

9. The display device of claim 8, wherein the material complexed plate comprises a cable hole which is formed in at least a portion of the receiving portion, and formed to penetrate the front skin, the core, and the rear skin,
wherein the cut-out portion is located between the cable hole and the plurality of slit grooves.

10. The display device of claim 9, wherein the cut-out portion comprises:
a first slit located between the cable hole and the plurality of slit grooves; and
a second slit which is located between the cable hole and the first slit, and spaced apart from the first slit,
wherein a width of the first slit is smaller than a width of the second slit.

11. The display device of claim 8, wherein the cut-out portion is formed in at least a portion of a boundary between the outer part or the receiving portion.

12. The display device of claim 1, wherein a thickness of the flat portion is larger than a thickness of the receiving portion.
